(19) United States
(12) Patent Application Publication
(10) Pub. No.: US 2007/0177437 A1
(43) Pub. Date: Aug. 2, 2007

(54) Nano molecular modeling method

(76) Inventor: Hong Guo, Brossard (CA)

Correspondence Address: GOUDREAU GAGE DUBUC, 2000 MCGILL COLLEGE, SUITE 2200, MONTREAL, QC, H3A 3H3, CA

(21) Appl. No.: 11/568,103

(22) PCT Filed: Apr. 19, 2005
(86) PCT No.: PCT/CA05/00598

§ 371 Date: Oct. 19, 2006

Related U.S. Application Data
(60) Provisional application No. 60/563,446, filed on Apr. 20, 2004.

(51) Int. Cl. G11C 7/06

(52) U.S. Cl. 365/189.07

(57) ABSTRACT

A nano-technology modeling method wherein a group of atoms and an interaction thereof to an open environment are defined by Hamiltonian matrices and overlap matrices, matrix elements of the matrices being obtained by a tight-binding (TB) fitting of system parameters to a first principles atomistic model based on density functional theory (DFT) with non-equilibrium density distribution.

### FIELD OF THE INVENTION

The present invention relates to molecular modeling in the nano scale. More specifically, the present invention is concerned with a modeling method for nano systems.

### BACKGROUND OF THE INVENTION

Electronic device modeling methods have allowed an incredible development rate of microtechnology, by allowing engineers to predict the performance of a technology emerging at the time.

Similarly, nano-tech modeling methods would allow developing nano-electronics and nanotechnology to a full potential by enabling rapid design and validation of nano-scale materials and devices. Such nano-tech modeling methods for electronic device properties do not yet exist today for lack of proper theoretical formalism and of associated modeling tool.

As people in the art are well aware of, the properties of electronic systems at a nano-meter scale are strongly influenced by quantum mechanical effects, and derive from conceptually different device structures and operation principles. State-of-the-art electronic device modeling methods based on atomistic quantum mechanical first principles can currently only deal with systems involving roughly 1000 atoms or less, due to theoretical and numerical complexities. This severely limits their relevance for most large scale nanotechnology systems.

A remarkable miniaturization of semiconductor microelectronics has been taking place over the past several decades. If the miniaturization trend is to continue, devices are expected to reach a physical limit in a near future (see The International Technology Roadmap for Semiconductors, Technical Report, Semiconductor Industry Association, San Jose, Calif. (2003)). At that time, electronic devices will no longer work under designs as currently known, and will require an understanding of conceptually different device structures and operation principles.

Therefore, a challenge in the field of nanoelectronics is to develop adequate modeling methods.

As it stands now, efforts in the field of nanoelectronics have been conducted in at least two distinct domains. On the one hand, an “up-to-bottom” approach of microtechnology applies the scaling down of semiconductor microtechnology to the device feature size regime of below 50 nm. Quantum effects are expected to play a very important role for the operation of such ultra-small semiconductor devices. On the other hand, there has been the advent of “bottom-to-up” fabrication of devices from assembling individual molecules and groups of atoms at a length scale of about 1 nm, in which quantum effects not only play an important role, but also provide some of the basic device principles. The latter efforts tend to a scaling up of sub-nanometer scale devices such as single molecule devices and nano-electromechanic systems (known as NEMS).

Importantly, a present trend seems to indicate that these efforst are leading to a near future where nanoelectronics are expected to operate, hence a need for a molecular modeling methods to understand how such nanoelectronic devices work.

Although the modeling of semiconductor technology has a long history, its basic physical principle lies in classical or semi-classical physics, where quantum effects and atomistic details of the devices are largely ignored. Such modeling is heavily dependent on material and electronic parameters obtained by fitting to experimental data, which is becoming increasingly expensive and less reliable as device size continues to shrink. Furthermore, due to fundamental limitations, traditional microelectronic devices theory and modeling methods are insufficient and even invalid when quantum effects are involved, for example in the case of charge transport at the up-coming scale between 30 nm and 50 nm.

For full quantum mechanical first principles atomistic analysis of materials and electronics, a most widely used and most powerful formalism is the density functional theory (known as DFT). Since DFT is able to solve quantum mechanic model including all atomic details, it has been applied to many different problems to predict structural and mechanical properties of materials, optical and electronic properties of matter, molecular modeling in chemistry, biological and drug-design applications, etc. The success of DFT is evidenced by the Nobel Prize awarded to its original discoverer, Prof. Walter Kohn, in 1998. However DFT methods of analysis of materials property has so far been applied to systems involving, in most cases, from a few tens to a few hundred atoms due to the complexity of the theory and its time consuming numerical procedure. In other words, at present, quantum mechanical atomistic analysis methods are limited to systems with a linear size less than about 5 nm.

At a technical level, a typical nano-electronic device can be considered as comprising a device scattering region, such as the channel region of a Si transistor, a large molecule, or a collection of atoms for example, contacted by a number of long and different electrodes where bias voltages are applied and electric current collected. There can be a number of gates with gate voltages modulating the current flow. The typical nano-electronic device is further interacting with an environment such as a substrate or other devices nearby.

To deal with such a typical nano-electronic device, a most realistic approach is clearly based on DFT, which has a potential to handle large systems and includes most of the important microscopic physics. However, DFT methods are so far largely limited to two classes of problems at equilibrium, namely electronic states of finite system such as an isolated molecule, and electronic states of periodic system consisting of repeated units.

The typical nano-electronic device, however, is neither finite nor periodic, and is typically operating under non-equilibrium conditions. First, it is not finite since it is connected to a number of electrodes and interacts with an environment involving a practically infinite number of atoms. Second, it is not periodic since it does not have translational symmetry. Third, it is away from equilibrium since external bias voltages are applied to drive a current flow. These features of the typical nano-electronic device need be resolved with a nano-modeling method.

To date, there have been a few theoretical attempts for analyzing quantum transport of devices at a truly molecular scale using DFT (see for example: N. D. Lang, Phys. Rev. B, 52, 5335, (1995); K. Hirose, M. Tsukada, Phys. Rev. B 51, 5278 (1995); C. C. Wan, J. L. Mozos, G. Taraschi, J. Wang and H. Guo, Appl. Phys. Lett., 71, 419, (1997); H. J. Choi and J. Ihm, Phys. Rev. B, 59, 2267, (1999); J. Taylor, H. Guo and J. Wang, Phys. Rev. B 63 245407 (2001); J. Taylor, Ph. D. thesis, McGill University (2000); M. Brandbyge, J. L. Mozos, P. Ordejdn, J. Taylor and K. Stokbro, Phys. Rev. B 65 165401 (2002)).

Although fully recognizing the important contributions of these works to molecular electronics theory, it is however noted that they have a number of fundamental limitations. For example; methods based on periodic boundary condition cannot deal with open device structures, and methods based on the jellium model for device electrodes (rather than realistic atomic electrodes) are too crude to deal with device-electrode contacts. In addition, most existing methods can only treat a number of atoms less than a few hundred and are very difficult, if applicable at all, to extend to much larger scale.

At present, the most promising atomistic modeling methods in the nano-range are based on carrying out DFT analysis within the Keldysh non-equilibrium Green's function (NEGF) formalism. This technique, as first developed by the present inventors, allows parameter-free analysis of devices involving as large as about 1000 atoms in the device channel region (see J. Taylor, H. Guo and J. Wang, Phys. Rev. B 63 245407 (2001); J. Taylor, Ph. D. thesis, McGill University (2000); H. Mehrez, Ph. D. thesis, McGill University (2001); B. Larade, Ph. D. thesis, McGill University (2002); P. Pomorski, Ph. D. thesis, McGill University (2002); P. Pomorski, C. Roland, H. Guo and J. Wang, Phys. Rev. B 70, 115408 (2004); P. Pomorski, Phys. Rev. B 67, 161404 (2003); P. Pomorski, L. Pastewka, C. Roland, H. Guo and J. Wang, Phys. Rev. B 69, 115418 (2004)).

Using a NEGF-DFT method they have developed, the present inventors have so far investigated a number of important issues of nano-electronics, including the quantitative comparison and agreement with experimental data on transport properties of molecular (C.-C. Kaun, B. Larade and H. Guo, Phys. Rev. B 67, Rapid Communication, 121411 (2003), C. C. Kaun and Hong Guo, Nano Letters, 3, 1521 (2003)), metallic (see H. Mehrez, A. Wlasenko, B. Larade, J. Taylor, P. Grütter, and H. Guo, Phys. Rev. B, 65, 195419 (2002)), and Carbon nanowires (see B. Larade, J. Taylor, H. Mehrez, and H. Guo, Phys. Rev. B, 64, 75420 (2001)); the understanding of electronic levels of molecular devices (see B. Larade, J. Taylor, Q. R. Zheng, H. Mehrez, P. Pomorski and H. Guo, Phys. Rev. B, 64, 195402 (2001)); current triggered vibrational excitations in molecular transistors (see S. Alavi, B. Larade, J. Taylor, H. Guo and T. Seideman, special issue of Molecular electronics in Chemical Physics, 281, 293 (2002)); Carbon nanotubes (see J. Taylor, H. Guo and J. Wang, Phys. Rev. B 63 245407 (2001); J. Taylor, Ph. D. thesis, McGill University (2000); C.-C. Kaun, B. Larade, H. Mehrez, J. Taylor, and H. Guo, Phys. Rev. B 65, 205416 (2002)); fullerene tunnel junctions (see C. Roland, B. Larade, J. Taylor, and H. Guo, Physical Review B, 65, Rapid Communication, R041401 (2002); J. Taylor, H. Guo and J. Wang, Phys. Rev. B 63, Rapid Communication, 121104 (2001)); and non-equilibrium charge distribution and nanoscale capacitors (see P. Pomorski, C. Roland, H. Guo and J. Wang, Phys. Rev. B 67, 161404 (2003)). These and a number of other investigations of the present inventors have established a basic working formalism for predicting nano-electronics operation from quantum principle at devices length scales of about 5 nm.

Still, a most important and urgent task in nanoelectronic device theory is to develop a theoretical formalism and an associated modeling method, based on atomistic quantum mechanical principles, which are powerful and accurate enough to analyze and predict material and device properties from about 1 nm molecular electronics all the way to about 50 nm semiconductor technology. This means a first principles method that allows accurate quantum analysis involving from one to about one million atoms.

Therefore there is a need for a molecular modeling method for nanoscale systems.

### SUMMARY OF THE INVENTION

More specifically, there is provided a method for modeling a system including a group of atoms and an open environment comprising other atoms, the group of atoms interacting with the open environment, whereby the group of atoms and an interaction thereof with the open environment are defined by Hamiltonian matrices and overlap matrices, matrix elements of the matrices being obtained by a tight-binding (TB) fitting of system parameters to a first principles atomistic model based on density functional theory (DFT) with a non-equilibrium density distribution.

Other objects, advantages and features of the present invention will become more apparent upon reading of the following non-restrictive description of embodiments thereof, given by way of example only.

### BRIEF DESCRIPTION OF THE DRAWINGS

In the appended drawings:

FIG. 1 is a plot of fitted functions for parameterizing on-site Hamiltonian of CNTs (Carbon Nanotubes), according to the present invention;

FIG. 2 is a plot of fitted functions for parameterizing two-wall carbon nanotube intra-shell off-site Hamiltonian according to the present invention, as compared with ab initio results Hamiltonian;

FIG. 3 is a plot of fitted functions for parameterizing Carbon nanotube inter-shell Hamiltonian according to the present invention, as compared with ab initio results Hamiltonian;

FIG. 4 shows the transmission coefficient T(E) as a function of energy E for a (5,5) carbon nanotube, obtained by ab initio Hamiltonian (solid black line) and obtained by parameterized TB Hamiltonian (dashed red line); and

FIG. 5 shows I-V curves for a (5,5) carbon nanotube obtained from the transmission T shown in FIG. 4.

### DESCRIPTION OF EMBODIMENTS OF THE INVENTION

There is provided a multi-scale modeling method, which bridges a length scale gap between the two domains of current nano-systems discussed above, and therefore provides a powerful means to help developing a future generation of electronic devices, and has a wide range of applicability in the understanding and prediction of material, electronic and transport properties of nanoscale systems.

Based on previous methods developed so far as described hereinabove, the present method allows a qualitative leap, whereby nanosystems comprising from a single atom all the way to about 50 nm may be modeled.

The present method for bridging length scales in nano-electronics modeling has been developed along four directions, as follows: for devices involving up to about a few thousands atoms, even up to 10,000 atoms, the method comprises using a self-consistent first principles atomistic formalism; for devices involving up-to one million atoms, the method comprises using a tight binding atomistic formalism; the method is developed for a wide range of application formalisms for nano-electronics device modeling; and the method comprises using powerful computer cluster system for parallel computation.

A nano-electronic device as referred to herein is a system including a group of atoms (referred to as the device-group′) interacting with an open environment (referred to as the environmental-group) comprising other atoms or/and a continuum of material. The system is specified by a three-dimensional structure of atoms, including their positions and types, in a device scattering region thereof, and electrodes. Mathematically, this system is defined by a Hamiltonian operator Ĥ, which includes electron-electron and electron-ion interactions, the environmental-group and external forces, so that once this Hamiltonian operator Ĥ is known all system properties may be deduced.

For devices involving up to a few thousands atoms, the method comprises using a self-consistent first principles atomistic formalism. More specifically, the method uses a DFT atomistic approach to predict device properties fully self-consistently without resorting to any phenomenological parameter, as described elsewhere by the present inventors (see J. Taylor, H. Guo and J. Wang, Phys. Rev. B 63 245407 (2001); J. Taylor, Ph. D. thesis, McGill University (2000); H. Mehrez, Ph. D. thesis, McGill University (2001); B. Larade, Ph. D. thesis, McGill University (2002); P. Pomorski, Ph. D. thesis, McGill University (2002)).

In DFT, as described in the art (See, for example, Density-Functional Theory of Atoms and Molecules, R. G. Parr and W. Yang, (Oxford University Press, New York, 1989)), the Hamiltonian operator Ĥ of the system is determined as a functional of a local electron charge density ρ(r), i.e. Ĥ=Ĥ[ρ(r)]. In a transport problem, the system has open boundaries connecting to electrodes and operates under external bias and gate potentials, which drive the device to non-equilibrium, i.e. the environmental-group comprises one or more electrodes and possibly metallic gates and substrates where the device is embedded, and the device-group is the electronic device scattering region, which comprises at least one atom. The charge density ρ(r) is thus to be determined under such conditions. Obtaining Ĥ and ρ(r) is a self-consistent process, wherein Ĥ is obtained from ρ(r), and then, using Ĥ, ρ(r) is evaluated, in an iterative process until Ĥ converges. As shown before by the present inventors, the device conditions may be accounted for by using the Keldysh non-equilibrium Green's function (NEGF) for example, to construct ρ(r) from Ĥ (J. Taylor, H. Guo and J. Wang, Phys. Rev. B 63 245407 (2001); J. Taylor, Ph. D. thesis, McGill University (2000); H. Mehrez, Ph. D. thesis, McGill University (2001); B. Larade, Ph. D. thesis, McGill University (2002); P. Pomorski, Ph. D. thesis, McGill University (2002)).

The details of this NEGF-DFT formalism is rather technical and only its main advantages over other known formalisms will be briefly summarized herein for concision purpose, as follows:
(i) NEGF-DFT allows calculating the charge density ρ(r) for open quantum systems under a bias voltage entirely self-consistently without resorting to phenomenological parameters;
(ii) since ρ(r) is constructed from NEGF, the non-equilibrium nature of device operation is handled properly;
(iii) NEGF-DFT treats atoms in the device scattering region and in the electrodes at equal-footing, therefore allowing realistic electrodes and contacts modeling;
(iv) NEGF treats discrete and continuum parts of electron spectra at equal footing, so that all electronic states are included properly into the calculation of Ĥ.

It is to be noted that NEGF-DFT has already been applied to devices with sizes and complexities no other atomistic formalism of the art could handle.

In the present method, the NEGF-DFT formalism is used to allow modeling of systems involving a large number of atoms, based on the fact that the calculation cost of the system Hamiltonian Ĥ scales as O (N), which means that the cost scales linearly with the atomic degrees of freedom (N) inside the device scattering region.

More precisely, it was shown that a main computational bottleneck of NEGF-DFT method is the calculation and inversion of a large matrix {Ĥ_{μv}} in order to calculate the NEGF, which is needed in constructing the charge density. For example, considering nine orbitals (s, p, d orbitals) per atom, in the case of 10,000 atoms, this matrix is 90,000×90,000, and it is prohibitively time consuming to invert such a large matrix tens of times during the DFT iteration. However, it is noted that the atomic orbitals decay rapidly to zero from the atomic core, which results in that distant atoms do not have a direct orbital overlap. Furthermore, it has been shown that it is possible to “cut off” the orbital tails at some cut-off distance about several Angstroms while still maintaining high accuracy (P. Ordejdn, E. Artacho and Josh M. Soler, Phys. Rev. B. 53, R10441 (1996)).

Hence, due to the finite ranginess of the atomic basis, a matrix element Ĥ_{μv} is zero if atoms u and v are located further than twice the cut-off distance. Using this fact, the present method comprises cutting the device scattering region into a number of sub-boxes each having a linear size at least equal to twice the cut-off distance. As a result, atoms in each sub-box only “interact” with other atoms in the same sub-box and in nearest-neighbor sub-boxes. The resulting matrix {Ĥ_{μv}} is then block-tridiagonal and may be inverted within O (N²) operations (instead of O (N³) for dense matrices).

In addition, to calculate charge density from non-equilibrium Green's functions, only a very small portion of the NEGF matrix, which is related to the inverted {Ĥ_{μv}}, is needed, and the calculation of NEGF is further reduced to O (N) operations because most of its elements do not need to be calculated. Indeed, technically, NEGF is calculated from the Keldysh equation G^{<}=G^{r}Σ^{<}G^{a}, where G^{r,a} are retarded and advance Green's functions obtained by inverting the {Ĥ_{μv}} matrix. The matrix Σ^{<}, referred to as the self-energy, describes charge injection from the electrodes, and couples the scattering region to the electrodes. Most matrix elements of Σ^{<} are zero, except those corresponding to electrode atoms in the immediate neighboring sub-boxes to the scattering region. Because of this form of the self-energy Σ^{<}, only a part of the Green's functions G^{r,a} needs to be calculated in order to obtain the NEGF G^{<}. Therefore, due to this O (N) nature, the matrix to be inverted in computing NEGF is not the full 90,000×90, 000 matrix (in the above example of 10,000 atoms), but reduces to a number of sub-matrices with a size corresponding to the orbitals in sub-boxes. The size of these sub-matrices is estimated to be about 3,000×3,000 using a typical value of orbital cut-off (as assessed for example in P. Ordejdn, E. Artacho and Josh M. Soler, Phys. Rev. B. 53, R10441 (1996)) between about 5-6 Å, and this sub-matrix size does not increase when the total number of atoms increases. As people in the art will appreciate, a matrix of such size is easily inverted, and inversion of a number of them is highly parallelizable.

Therefore, the present method allows handling systems as large as a few thousands atoms totally self-consistently.

For devices involving up-to one million atoms, the present method further comprises using a tight binding atomistic formalism to model the about 50 nm nano-electronic devices, where a very large number of atoms is involved. Although this scale is too large for the NEGF-DFT method even considering the development described hereinabove, it may be handled by the present method by using a parameterized tight-binding (TB) model in which a device Hamiltonian Ĥ^{TB} is parameterized instead of being dynamically calculated. For device modeling, Ĥ^{TB} is to reflect the presence of external fields driving the current flow, and other open environmental effects such as the charge transfer from the electrodes during transport, which existing TB methods in the art do not allow. Therefore existing TB methods appear unsatisfactory for nano-electronics modeling.

The present method makes use of the NEGF-DFT method developed by the present inventors and described hereinabove to calculate Hamiltonian matrix {Ĥ_{μv}} on devices with a smaller number of atoms, as a function of external bias and gate fields. The resulting {Ĥ_{μv}} is then fitted into a TB form {Ĥ_{μv}^{TB}}. The resulting {Ĥ_{μv}^{TB}} thus obtained includes all the effects of the device environment, and therefore reproduces, to a large extent, the full self-consistent transport results of the original device model {Ĥ_{μv}}.

For much lager systems, {Ĥ_{μv}^{TB}} is used to calculate transport directly, which saves the time consuming self-consistent DFT iteration of computing {Ĥ_{μv}}. Cases with carbon devices were successful.

A number of ways are contemplated in order to determine an optimized strategy for parameterizing Ĥ_{μv}^{TB} to reflect the device operation environment. As will be further described hereinafter, these ways include for example directly using bias and gate voltages as fitting parameters; parameterizing using average electric field strength inside the scattering region; and parameterizing using local orbital charge densities.

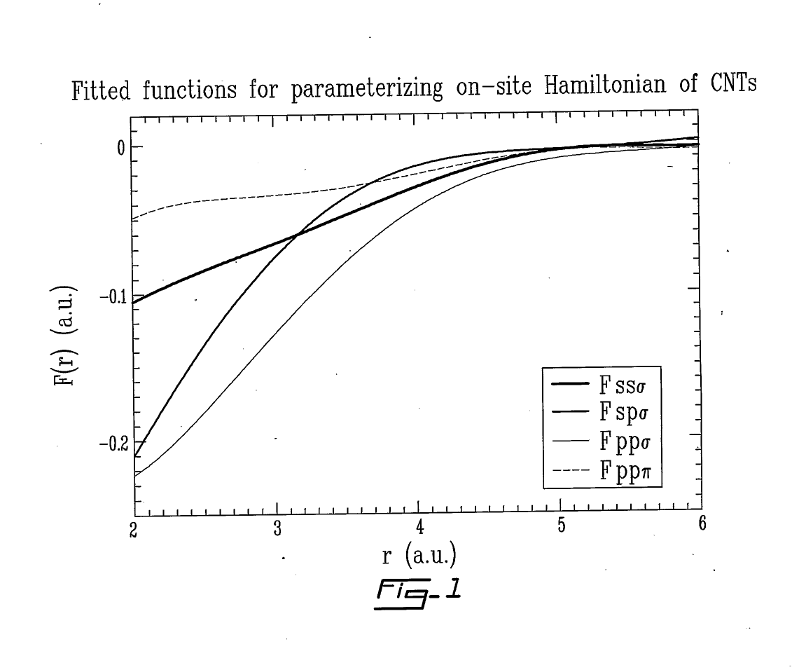

For non-equilibrium charge and spin transport, the fitting of TB parameters is done by fitting to the Hamiltonian matrix elements obtained from the ab initio NEGF-DFT method described above. Examples of the fitted parameters are in FIGS. 1-3.

The fitting of the TB parameters may further be facilitated by fitting to the electron transmission coefficient T (E, V_{b}, V_{g}), which is obtained from the first principles DFT methods, and which is a function of electron energy E, external bias voltage V_{b}, and external gate voltage V_{g}. The transmission coefficient T (E, V_{b}, V_{g}) describes the probability for an electron to traverse the device-group from one part of the environmental-group (an electrode) to another part of the environmental-group (a second electrode).

This fitting of the TB parameters may further be facilitated by further fitting to a bias dependent density of states, DOS (E, V_{b}, V_{g}), calculated from first principles, and by further fitting to equilibrium properties of the device system (at zero bias potentials). Furthermore, it may be contemplated fitting to charge and spin current, the non-equilibrium charge distribution that is established during current flow, the quantum mechanical forces with and without external bias and gate voltages.

The transmission coefficient T (E, V_{b}, V_{g}) used to fit the TB parameters is obtained from a first principles quantum mechanical calculation, and fitting to T (E, V_{b}, V_{g}) comprises performing first principles quantum mechanical calculations on the device system to obtain T (E, V_{b}, V_{g}) and other equilibrium properties; performing TB calculations on the same system to obtain approximate transmission coefficient T^{TB} (E, V_{b}, V_{g}) and approximate equilibrium properties; and minimizing the difference between T (E, V_{b}, V_{g}) and T^{TB} (E, V_{b}, V_{g}), as well as between the equilibrium properties, by adjusting the TB parameters for all applied voltages.

A similar fitting procedure applies for fitting to other properties.

From the foregoing, it appears that the full self-consistent NEGF-DFT method of the nano-modeling as described hereinabove can be used to generate TB parameters which depend on external fields, thereby allowing nano-electronics modeling involving a very large number of atoms. As a result, the method may allow modeling devices involving one million atoms.

The application possibility of the present nano-modeling method is extremely wide ranged. It may be applied for example to the following:
(i) The investigation of nanotube field effect devices on semiconductor substrate, as experimentally fabricated (see details of fabrication in J. Appenzeller, J. Knoch, V. Derycke, R. Martel, S. Wind, and Ph. Avouris, Phys. Rev. Lett. 89, 126801 (2002)). Nano-electronic devices on realistic substrates have never been investigated theoretically to any satisfaction due to the large number of atoms involved, but may be within reach with the present nano-modeling method.
(ii) Study of electric conduction in self-assembled monolayer (SAM) systems. SAM is a very important system and exactly how charge flows through a SAM must now be understood.
(iii) Investigation of Si devices at a scale of 10 to 50 nm channel length. Leakage current of ultra-thin oxides may also be calculated. It is also possible to investigate other nano-meter scale semiconductor devices made by compound semiconductors.
(iv) The study of AC transport properties of nano-electronics. As discussed elsewhere before by the present inventors, new physics arise in AC transport at nanoscale due to induction, which becomes much stronger for systems with a reduced density of states (see B. G. Wang, J. Wang and H. Guo, Phys. Rev. Lett, 82, 398 (1999); C. Roland, M. B. Nardelli, J. Wang and H. Guo, Phys. Rev. Lett. 84, 2921 (2000)).
(v) Modeling of transport properties of hybrid devices including normal-superconductor, normal-magnetics, and normal-biomolecular hybrids: superconductor and magnetic materials contribute more complicated self-energies to the NEGF, but relevant formulas have already been derived for these systems (see H. Mehrez, J. Taylor, H. Guo, J. Wang and C. Roland, Phys. Rev. Lett., 84, 2682 (2000); Q. F. Sun, H. Guo, and T. H. Lin, Phys. Rev. Lett. 87, 176601 (2001); Y. Wei, J. Wang, H. Guo, H. Mehrez and C. Roland, Phys. Rev. B. 63, 195412 (2001); N. Sergueev, Q.-F. Sun, H. Guo, B. G. Wang and J. Wang, Phys. Rev. B 65, 165303 (2002)), and are ready to be implemented into the present nano-modeling method.
(vi) Charge conduction in bio-molecules may be investigated. Bio-molecules such as DNA may be used to build nanoscale networks of conductors, they may also conduct charge themselves. These properties are strongly influenced by environmental effects such as the presence of water molecules and their study involves a large number of atoms.
(vii) Current induced structural changes may be studied. The present method allows the calculation of current-induced quantum mechanical forces, molecular vibrational spectrum during current flow, and other current triggered molecular dynamics.
(viii) Calculation of switching speed of current in nanoscale devices. When a voltage pulse is applied to a nanoelectronic device, the current turns on and turns off according to the pulse duration. The present method allows the calculation of this switching speed including all quantum contributions to resistance, capacitance and inductance.
(ix) Investigation of how two or more nanoelectronic devices couple and work in a circuit. Interaction between devices at the nanoscale is a very important problem and may be solved by the present method.
(x) STM simulations: scanning tunneling microscopes (STM) are commonly used in a wide range of fields by passing a current through the subject of study into a substrate. The present method may be used to predict and help explaining STM images without resorting to approximations used in conventional STM theory.

The present nano-modeling method may further be applied to model the coupling strength between electrons and molecular vibrations during current flow in a nanoscale device, as well as the modeling of inelastic current and local heating properties of the device.

FIGS. 1 to 5 present results obtained by the present method, in modelling of various carbon nanotube systems (CTN).

Unlike prior art methods for obtaining tight-binding parameters by fitting ab initio calculated electronic band structures and/or total energies of various different atomic structures, the present method provides a set of tightbinding-like parameters by directly parameterizing ab initio calculated Hamiltonian matrix elements. On various carbon nanotube systems, as show in FIGS. 1 to 5, the obtained parameters reproduce the ab initio Hamiltonian matrix elements very precisely and are transferable within a class of atomic structures with similar topological properties. The reliable parameterized Hamiltonian then reproduces all transport results of the original ab initio calculated Hamiltonian.

The procedures for obtaining the parameters as plotted in FIGS. 1 to 5 is recalled below.

First, the Hamiltonian matrix {H_{μv}} is obtained by the NEGF-DFT method. For parameterization of this Hamiltonian, the on-site part, related to each single atom in the structure, i.e. the atomic orbital index μ, v of the on-site matrix elements {H_{μv}} belonging to the same atom; and the hopping part of the matrix elements, related to two adjacent atoms, are dealt with separately, as follows:

(i) On-site part: for a carbon nanotube (CNT) system, a sp³ basis set is used. By transforming each 4×4 on-site submatrix of the Hamiltonian matrix {H_{μv}} into its equivalent form defined on local coordinates of each site, it is found that the energy difference between p-orbitals perpendicular to and parallel to the CNT surface is as large as 5 eV, indicating that a conventional tight-binding scheme with a constant on-site p-orbital energy can not reproduce the ab initio Hamiltonian {H_{μv}}. In addition, it is found that the Hamiltonian element between s-orbital and the p-orbital perpendicular to the CNT surface is about 1 eV, in contrast the zero value adopted by the conventional tight-binding scheme. Further calculation shows that both the energy difference between p-orbitals and the small element between s-orbital and the p-orbital perpendicular to the CNT surface affect transport results significantly, and that, therefore, they can not be neglected. Based on the above analysis, the matrix element values of the on-site part of {H_{μv}} are decomposed into contributions from every neighbor atoms of the site. In this way, environment effects on the site is included and the matrix elements are parameterized very precisely with a maximum error being within tens of meV. The decomposition is performed around the Slater-Koster two-center approximation, which was originally used in the conventional tight-binding scheme for the hopping part of the Hamiltonian. With the Slater-Koster two-center approximation, the 16 on-site elements of {H_{μv}} for each site i are written as follows:

$${E}_{ss}^{i} = {E}_{z}^{0} + {\sum }_{j ( \neq i )} {F}_{ss σ} ( {r}_{ij} )$$

$${E}_{s α}^{i} = {\sum }_{j ( \neq i )} ( {{e}^{⋒}}_{α} \cdot {{r}^{⋒}}_{ij} ) {F}_{sp σ} ( {r}_{ij} )$$

$${E}_{α β}^{i} = {E}_{α}^{0} {δ}_{α β} + {\sum }_{j ( \neq i )} \{ ( {{e}^{⋒}}_{α} \cdot {{r}^{⋒}}_{ij} ) ( {{e}^{⋒}}_{β} \cdot {{r}^{⋒}}_{ij} ) {F}_{pp σ} ( {r}_{ij} ) + [ ( {{e}^{⋒}}_{α} {{e}^{⋒}}_{β} ) - ( {{e}^{⋒}}_{α} \cdot {{r}^{⋒}}_{ij} ) ( {{e}^{⋒}}_{β} \cdot {{r}^{⋒}}_{ij} ) ] {F}_{pp π} ( {r}_{ij} ) \}$$

where α, β are coordinates x, y, z; Eₛ° and E_{>>}° are atomic orbital energies of corresponding isolated atom; and the functions F_{ssσ}, F_{spσ}, F_{ppσ}, and F_{ppπ} are determined numerically by fitting the ab initio on-site elements of {H_{μv}} for a number of different CNT structures. Those fitted functions F_{ssσ}, F_{spσ}, F_{ppσ and F}_{ppπ}, are plotted as a function of distance r in FIG. 1.

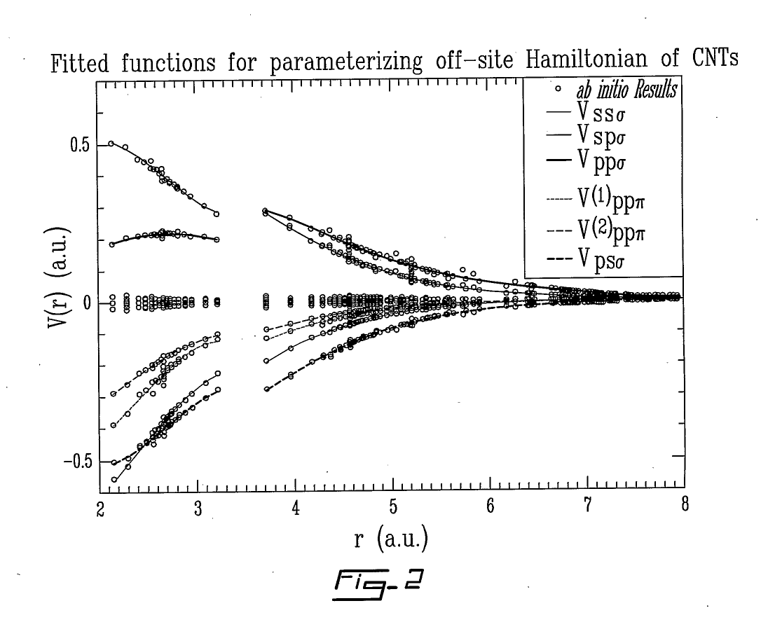

(ii) Hopping part: Similar to the analysis on the on-site part of {H_{μv}}, local coordinates are redefined for each pair of atoms and then the corresponding 4×4 hopping submatrix of {H_{μv}} is transformed into its equivalent form defined on the redefined local coordinates. By plotting all the matrix elements defined on the local coordinates against distance between the pair of atoms, it is found that the elements between p-orbitals perpendicular to the CNT surface and the elements between p-orbitals parallel to the CNT surface fall on two distinctly different curves. The energy difference of the two curves, at the distance between two nearest neighbor atoms, is as large as 1 eV, which indicates again that the conventional tight-binding scheme with no difference between p-orbitals can not reproduce the ab initio Hamiltonian {H_{μv}}. It is found that ignoring the difference between the two curves and using average values thereof completely changes the transport properties of the original ab initio Hamiltonian {H_{μv}}, which means that for reproducing the transport properties the difference between the two curves needs to be taken into account. Once the difference between p-orbitals is thus taken into account, all matrix elements of the hopping part of {H_{μv}}, after being transformed to local coordinates, is found either to be close to zero or to fall on six smooth curves V_{ssσ}, V_{spσ}, V_{psσ and V}_{ppπ}⁽¹⁾ and V_{ppπ}⁽²⁾, which are then be easily parameterized, with V_{psσ}=−V_{spσ}. FIG. 2 shows plots of V_{ssσ}, V_{spσ}, V_{psσ}, V_{ppσ}, V_{ppπ}⁽¹⁾ and V_{ppπ}⁽²⁾ as a function of distance r for constructing two-wall carbon nanotube intra-shell off-site Hamiltonian, as compared with ab initio results, showing an agreement between the TB method and the present NEGF-DFT method.

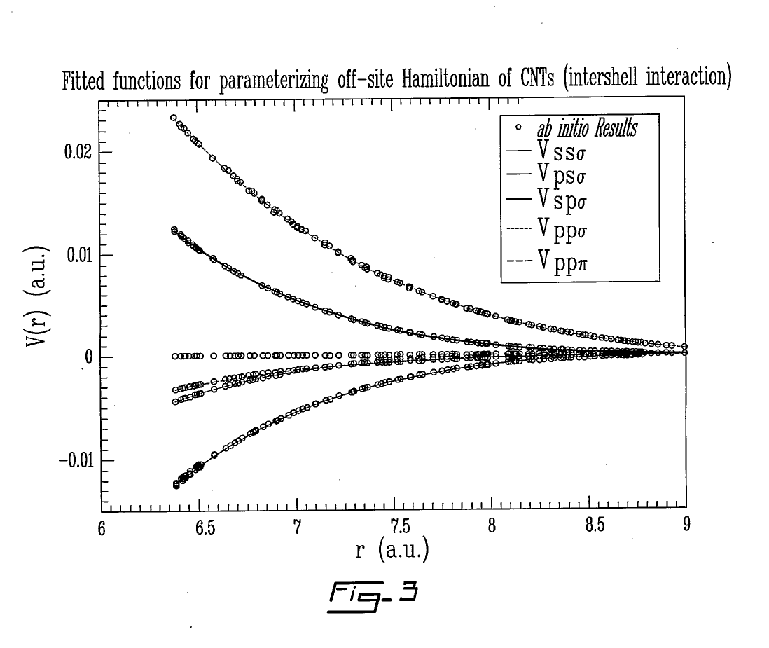

In multi-shell systems such as multi-wall CNTs, the intershell interaction is different from intrashell interaction. With a similar analysis as hereinabove, it is found that for intershell interaction, there is no observable difference between V_{ppπ}⁽¹⁾ and V_{ppπ}⁽²⁾ as in the case of intrashell interaction, and a single empirical curve describes the ppπ interaction. Then, as shown in FIG. 3, the intershell part of the ab initio Hamiltonian matrix elements can be well reproduced by smooth curves V_{ssσ}, V_{spσ}, V_{psσ}, V_{ppσ}, and F_{ppπ} as a function of distance r. Again, V_{psσ}=−V_{spσ}.

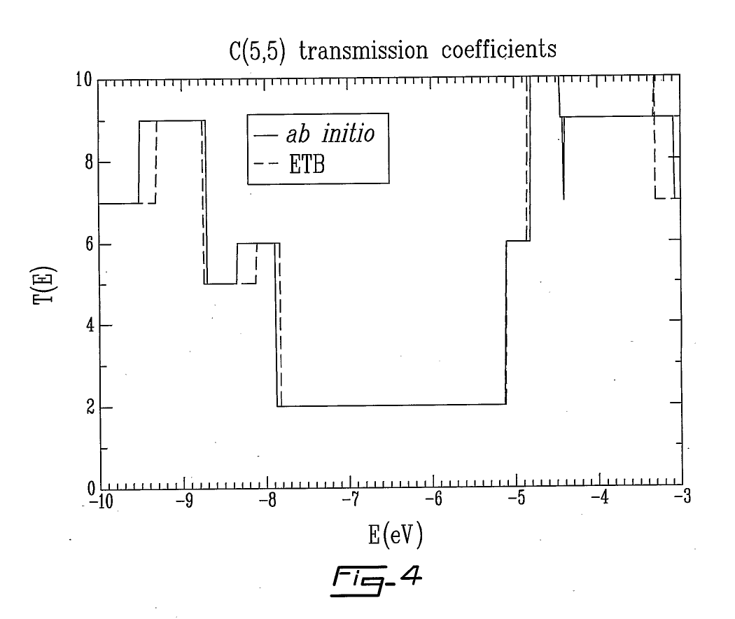

FIG. 4 illustrates the transmission coefficient T(E) as a function of energy E for a (5,5) carbon nanotube, obtained by ab initio Hamiltonian (solid black line) and by parameterized TB Hamiltonian (dashed red line). Almost perfect agreement is obtained.

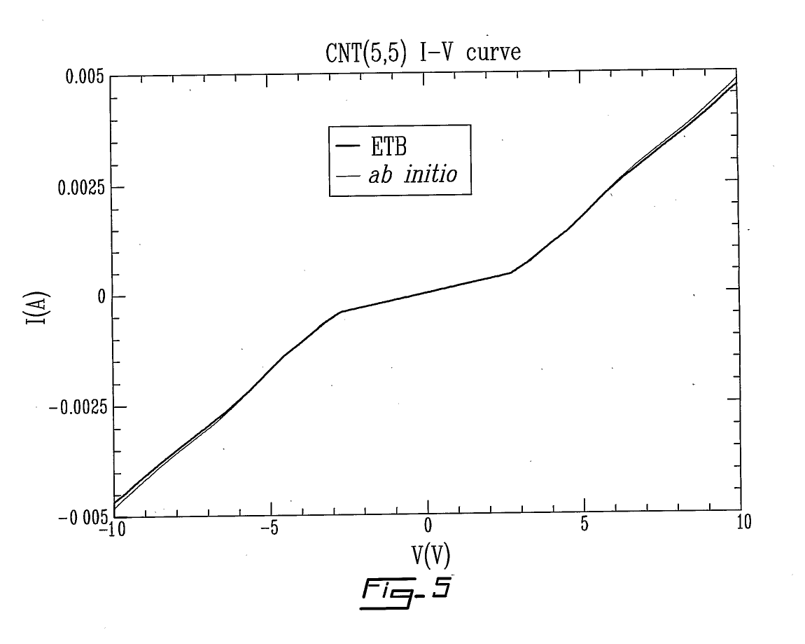

FIG. 5 illustrates I-V curves for a (5,5) carbon nanotube obtained from the transmission T shown in FIG. 4, showing an almost perfect agreement between the TB and the ab initio methods.

A number of other systems may be studied, including binary systems and alloys for example.

Generally stated, the present method, besides allowing all molecular modeling as well as any existing methods, allows modeling anything involving a current flow, including for example any electronic devices modeling, structure changes due to current (NEMS), sensors, storage device modeling, etc.

The present method further comprises using a distributed computing strategy, for both NEGF-DFT and TB methods discussed hereinabove, for parallel computation, allowed by the O (N) nature previously described.

People in the art should now be in a position to appreciate that, although the above description concentrated on discussing charge transport, the scope of the present method clearly goes way beyond this domain as it provides a completely new way to carry out large scale atomistic analysis. It is believed the theoretical and computational developments of this method will help to lay a solid foundation to a general modeling strategy for nanotechnology.

People in the art will appreciate that the present method, based on first principles quantum mechanical atomistic model, for predicting electronic, transport, and materials properties of nanoscale devices, is unique in its theoretical formalism and its modeling strategy. Importantly, the present method is capable of handling much larger number of atoms than presently available methods, and covers length scales from atomic level all the way to about 50 nm. The present method has therefore a wide range of application potential and unprecedented predictive power in the field of nano-electronics and nanotechnology.

Although the present invention has been described hereinabove by way of embodiments thereof, it may be modified, without departing from the nature and teachings of the subject invention as described herein.

1. A method for modeling a system including a group of atoms and an open environment comprising other atoms, the group of atoms interacting with the open environment, whereby the group of atoms and an interaction thereof with the open environment are defined by Hamiltonian matrices and overlap matrices, matrix elements of the matrices being obtained by a tight-binding (TB) fitting of system parameters to a first principles atomistic model based on density functional theory (DFT) with a non-equilibrium density distribution.

2. The method according to claim 1, comprising the steps of:
defining the non-equilibrium density distribution;
tight-binding (TB) fitting the system parameters to the first principles atomistic model based on density functional theory (DFT) with the non-equilibrium density distribution, to obtain the matrix elements; and
defining the Hamiltonian matrices and the overlap matrices of the group of atoms and of the interaction thereof with the open environment with the matrix elements.

3. The method according to claim 2, wherein the open environment comprises a continuum of material.

4. The method according to claim 2, wherein said step of defining the non-equilibrium density distribution comprises using Keldysh non-equilibrium Green's functions (NEGF).

5. The method according to claim 2, wherein said step of defining the non-equilibrium density distribution comprises solving a quantum statistical model of the system, the matrix elements obtained including effects of the open environment.

6. The method according to claim 2, wherein said step of tight-binding (TB) the fitting system parameters comprises fitting and obtaining tight-binding interactions with the open environment.

7. The method according to claim 2, wherein said step of tight-binding (TB) the fitting system parameters comprises at least one of fitting to an electron transmission coefficient T (E, V_{b}, V_{g}), fitting to a bias dependent density of states DOS (E, V_{b}, V_{g}), fitting to equilibrium properties of the system, and fitting to charge and spin current, a non-equilibrium charge distribution established during current flow, quantum mechanical forces with and without external bias and gate voltages.

8. The method according to claim 1, wherein the open environment comprises a continuum of material.

9. The method according to claim 8, wherein the system parameters include external electric fields, open boundary conditions and effects due to the open environment.

10. The method according to claim 8, wherein the non-equilibrium density distribution is obtained by Keldysh non-equilibrium Green's functions (NEGF).

11. The method according to claim 8, wherein the non-equilibrium density distribution is obtained by solving a quantum statistical model of the system, the matrix elements obtained including effects of the open environment.

12. The method according to claim 11, wherein the matrix elements obtained depend on at least one of an externally applied voltage, an electric field, a charge transfer and a spin transfer from the open environment.

13. The method according to claim 8, wherein the open environment comprises at least one electrode, the group of atoms comprises a scattering region of an electronic device, the scattering region comprising at least one atom, said method applying to charge and spin transport properties of the electronic device.

14. The method according to claim 13, wherein the open environment comprises a substrate where the electronic device is embedded.

15. The method according to claim 13, wherein the matrix elements obtained are used to model the electronic device, a current being driven through the electronic device by an application of an external bias voltage.

16. The method according to claim 8, wherein said tight-binding (TB) fitting is achieved by fitting to an electron transmission coefficient T (E, V_{b}, V_{g}), which is a function of electron energy E, external bias voltage V_{b}, and external gate voltage V_{g}.

17. The method according to claim 16, wherein the transmission coefficient T (E, V_{b}, V_{g}) is obtained from first principles quantum mechanical calculations.

18. The method according to claim 16, wherein said step of fitting to T (E, V_{b}, V_{g}) comprises:
obtaining T (E, V_{b}, V_{g}) and other equilibrium properties from first principles quantum mechanical calculations;
obtaining an approximate transmission coefficient T^{TB} (E, V_{b}, V_{g}) and approximate equilibrium properties by performing TB calculations; and
minimizing a difference between T (E, V_{b}, V_{g}) and T^{TB} (E, V_{b}, V_{g}), and a difference between the equilibrium properties and the approximate equilibrium properties, by adjusting the TB parameters for any applied voltages.

19. The method according to claim 16, wherein said step of tight-binding (TB) fitting further comprises fitting to a bias dependent density of states DOS (E, V_{b}, V_{g}).

20. The method according to claim 19, wherein the bias dependent density of states DOS (E, V_{b}, V_{g}), is calculated from first principles.

21. The method according to claim 19, wherein said step of fitting to a bias dependent density of states DOS (E, V_{b}, V_{g}) comprises:
obtaining the bias dependent density of states DOS (E, V_{b}, V_{g}) and other equilibrium properties from first principles quantum mechanical calculations;
obtaining an approximate bias dependent density of states DOS^{TB} (E, V_{b}, V_{g}) and approximate equilibrium properties by performing TB calculations; and
minimizing a difference between the bias dependent density of states DOS (E, V_{b}, V_{g}) and the approximate bias dependent density of states DOS^{TB} (E, V_{b}, V_{g}), and a difference between the equilibrium properties and the approximate equilibrium properties, by adjusting the TB parameters for any applied voltages.

22. The method according to claim 13, wherein said tight-binding (TB) fitting further comprises fitting to equilibrium properties of the system.

23. The method according to claim 22, wherein said fitting to equilibrium properties of the system comprises fitting to equilibrium properties of the system at conditions including with applied external voltages and without applied external voltages.

24. The method according to claim 22, wherein said fitting to equilibrium properties of the system comprises fitting to equilibrium properties of the system in at least one externally applied potential.

25. The method according to claim 13, wherein said tight-binding (TB) fitting further comprises fitting to charge and spin current, a non-equilibrium charge distribution established during current flow, quantum mechanical forces with and without external bias and gate voltages.

26. The method according to claim 22, wherein fitting to equilibrium properties of the system comprises:
obtaining the equilibrium properties from first principles quantum mechanical calculations;
obtaining approximate equilibrium properties by performing TB calculations; and
minimizing a difference between the equilibrium properties and the approximate equilibrium properties, by adjusting the TB parameters for any applied voltages.

27. The method according to claim 25, wherein said fitting to charge and spin current, a non-equilibrium charge distribution established during current flow, quantum mechanical forces with and without external bias and gate voltages comprises:
obtaining the charge and spin current and other equilibrium properties from first principles quantum mechanical calculations;
obtaining an approximate charge and spin current and approximate equilibrium properties by performing TB calculations; and
minimizing a difference between the charge and spin current and the approximate charge and spin current, and a difference between the equilibrium properties and the approximate equilibrium properties, by adjusting the TB parameters for any applied voltages.
